(19) United States
(12) Patent Application Publication
(10) Pub. No.: US 2011/0291277 A1
(43) Pub. Date: Dec. 1, 2011

(54) SEMICONDUCTOR DEVICE AND METHOD OF FORMING SEMICONDUCTOR DEVICE

(75) Inventor: Masatoshi YOSHIMATSU, Tokyo (JP)

(73) Assignee: ELPIDA MEMORY, INC., Tokyo (JP)

(21) Appl. No.: 13/116,770

(22) Filed: May 26, 2011

(30) Foreign Application Priority Data
May 28, 2010 (JP) 2010-123253

(51) Int. Cl. H01L 23/532

(52) U.S. Cl. 257/751; 257/E23.161

(57) ABSTRACT

A semiconductor device includes a wiring, a stack of first, second, and third films, and a contact plug. The stack of first, second, and third films is located over the wiring. The first, second, and third films are stacked in this order. The stack has an opening. The first film is made of the same material as the third film. The contact plug is in the opening. The contact plug is in contact with the wiring.

### BACKGROUND OF THE INVENTION

1. Field of the Invention

The present invention relates to a semiconductor device including an improved insulating film on a metal wiring and a method of forming the same.

Priority is claimed on Japanese Patent Application No. 2010-123253, May 28, 2010, the content of which is incorporated herein by reference.

2. Description of the Related Art

In semiconductor integrated circuit devices, copper (Cu) is used as a wiring material, and an insulating film having a low dielectric constant, which is referred to as “low-k”, is used as an interlayer insulating film to implement high speed and high performance. In recent years, copper wirings have been applied to semiconductor memory devices such as dynamic random access memories (DRAMs).

Japanese Unexamined Patent Application, First Publications, Nos. JP-A-2004-128050, JP-A-2004-296515, and JP-A-2004-319616 disclose a dual damascene (DD) method which is used to form the copper wirings. A DD process referred to as “via-first” having the following processes has been mainstreamed. First, a contact hole (via) is formed and then groove patterns for burying the copper wirings are formed.

In the DD process, a via etching process is performed until an interlayer insulating film is etched to a predetermined depth. However, when the thickness of the remaining interlayer insulating film is greater than a predetermined thickness, the groove pattern will not be preferably formed, which causes non-conduction. When an etching amount is excessive, a first copper wiring below the interlayer insulating film will be damaged. The copper wirings for DRAMs tend to be thickly formed. In this case, it is necessary to form a deep contact hole. When the deep contact hole is formed, it is necessary to precisely control a thickness of a film formed on a second cupper wiring which is disposed below the first copper wiring.

A silicon carbon nitride (SiCN) film, which is used as a diffusion barrier film for preventing copper from diffusing, is formed on the second copper wiring which is disposed below the first copper wiring. A low-k interlayer insulating film is formed on the silicon carbon nitride film. The low-k interlayer insulating film is etched by a dry etching process for forming a contact hole. An over-etching process is not sufficiently performed under the condition where the low-k interlayer insulating film does not have a high etch selectivity to the SiCN film. Thereby, the thickness of the remaining diffusion barrier film may not be uniform.

There is a method of forming the SiCN film with sufficiently great thickness and over-etching the low-k interlayer insulating film. However, when the thickness of the SiCN film is getting greater, capacitance of a wiring will be increased.

### SUMMARY

In one embodiment, a semiconductor device may include, but is not limited to, a wiring, a stack of first, second, and third films, and a contact plug. The stack of first, second, and third films is located over the wiring. The first, second, and third films are stacked in this order. The stack has an opening. The first film is made of the same material as the third film. The contact plug is in the opening. The contact plug is in contact with the wiring.

In another embodiment, a semiconductor device may include, but is not limited to, a substrate, a first interlayer insulating film, a wiring, a first diffusion barrier film, a second interlayer insulating film, a second diffusion barrier film, a third interlayer insulating film, and a contact plug. The first interlayer insulating film is located over the substrate. The wiring is located over the first interlayer insulating film. The wiring includes copper. The first diffusion barrier film is in contact with the wiring. The second interlayer insulating film is located over the first diffusion barrier film. The second diffusion barrier film is located over the second interlayer insulating film. The second diffusion barrier film includes the same material as the first diffusion barrier film. The third interlayer insulating film is located over the second diffusion barrier film. The third interlayer insulating film includes the same material as the second interlayer insulating film. The contact plug is in contact with the wiring. The contact plug includes copper. The contact plug has a side surface being in contact with the first diffusion barrier film, the second interlayer insulating film, the second diffusion barrier film, and the third interlayer insulating film.

In still another embodiment, a semiconductor device may include, but is not limited to, a transistor, a first interlayer insulating film, a wiring, a first film, a second film, a third film, and a contact plug. The first interlayer insulating film is located over the transistor. The wiring is located over the first interlayer insulating film. The wiring is electrically coupled to the transistor. The first film is in contact with the wiring. The second film is located over the first film. The third film is located over the third film. The third film is made of the same material as the first film. The contact plug is in contact with the wiring. The contact plug penetrates the first, second, and third films.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross-sectional elevation view illustrating a wiring structure in a step involved in a method of forming a semiconductor device according to one embodiment of the present invention;

FIG. 2 is a fragmentary cross-sectional elevation view illustrating the wiring structure in a step, subsequent to the step of FIG. 1, involved in the method of forming a semiconductor device according to one embodiment of the present invention;

FIG. 3 is a fragmentary cross-sectional elevation view illustrating the wiring structure in a step, subsequent to the step of FIG. 2, involved in the method of forming a semiconductor device according to one embodiment of the present invention;

FIG. 4 is a fragmentary cross-sectional elevation view illustrating the wiring structure in a step, subsequent to the step of FIG. 3, involved in the method of forming a semiconductor device according to one embodiment of the present invention;

FIG. 5 is a fragmentary cross-sectional elevation view illustrating the wiring structure in a step, subsequent to the step of FIG. 4, involved in the method of forming a semiconductor device according to one embodiment of the present invention;

FIG. 6 is a fragmentary cross-sectional elevation view illustrating the wiring structure in a step, subsequent to the step of FIG. 5, involved in the method of forming a semiconductor device according to one embodiment of the present invention;

FIG. 7 is a fragmentary cross-sectional elevation view illustrating the wiring structure in a step, subsequent to the step of FIG. 6, involved in the method of forming a semiconductor device according to one embodiment of the present invention;

FIG. 8 is a fragmentary cross-sectional elevation view illustrating a wiring structure in a step involved in a method of forming a semiconductor device according to the related art;

FIG. 9 is a fragmentary cross-sectional elevation view illustrating the wiring structure in a step, subsequent to the step of FIG. 8, involved in the method of forming the semiconductor device according to the related art;

FIG. 10 is a fragmentary cross-sectional elevation view illustrating the wiring structure in a step, subsequent to the step of FIG. 9, involved in the method of forming the semiconductor device according to the related art;

FIG. 11 is a fragmentary cross-sectional elevation view illustrating the wiring structure in a step, subsequent to the step of FIG. 10, involved in the method of forming the semiconductor device according to the related art;

FIG. 12 is a fragmentary cross-sectional elevation view illustrating the wiring structure in a step, subsequent to the step of FIG. 11, involved in the method of forming the semiconductor device according to the related art;

FIG. 13 is a fragmentary cross-sectional elevation view illustrating the wiring structure in a step, subsequent to the step of FIG. 12, involved in the method of forming the semiconductor device according to the related art;

FIG. 14 is a fragmentary cross-sectional elevation view illustrating the wiring structure in a step, subsequent to the step of FIG. 13, involved in the method of forming the semiconductor device according to the related art; and

FIG. 15 is a fragmentary cross-sectional elevation view illustrating the wiring structure in a step involved in the method of forming the semiconductor device according to the related art.

### DETAILED DESCRIPTION OF THE PREFERRED EMBODIMENTS

Before describing the present invention, the related art will be explained in detail, with reference to the drawings, in order to facilitate the understanding of the present invention.

FIGS. 8 to 14 are cross-sectional elevation views illustrating a wiring in steps involved in a method of forming a semiconductor device using a DD method of the related art.

As shown in FIG. 8, a semiconductor substrate 101 such as a silicon substrate, on which a first metal wiring 106 is formed using Cu, is prepared.

Here, an isolation region (not shown), which is formed of an insulating film such as a silicon oxide (SiO₂) film or a silicon nitride (Si₃N₄) film, is disposed in the semiconductor substrate 101 such as the silicon substrate. A diffusion region (an active region) is defined by the isolation region. An impurity is introduced into the diffusion region by the ion implantation process or the like.

A MOS transistor (not shown) having a gate electrode formed of polysilicon, tungsten or the like is formed on a main surface of the semiconductor substrate 1. The MOS transistor is electrically coupled to a wiring (not shown) or a contact plug (not shown) formed in an interlayer insulating film 102.

A diffusion barrier film 103, an interlayer insulating film 104 and a protection film 105 are sequentially stacked on the interlayer insulating film 102. The diffusion barrier film 103 is a SiCN film or the like. The diffusion barrier film 103 is formed by a plasma enhanced-chemical vapor deposition (PE-CVD) method. The diffusion barrier film 103 has a thickness of, for example, about 30 nm. The interlayer insulating film 104 is a low dielectric film such as a silicon oxycarbide (SiOC) film. The interlayer insulating film 104 is formed by a PE-CVD method. The interlayer insulating film 104 has a thickness of, for example, about 110 nm. The protection film 105 is a SiO₂ film. The protection film 105 is formed by a PE-CVD method. The protection film 105 has a thickness of, for example, about 50 nm. Copper is filled within a trench penetrating the stack of the diffusion barrier film 103, the interlayer insulating film 104, and protection film 105 to form a first metal wiring 106. The first metal wiring 106 is electrically coupled to the wiring or the contact plug formed in the interlayer insulating film 102.

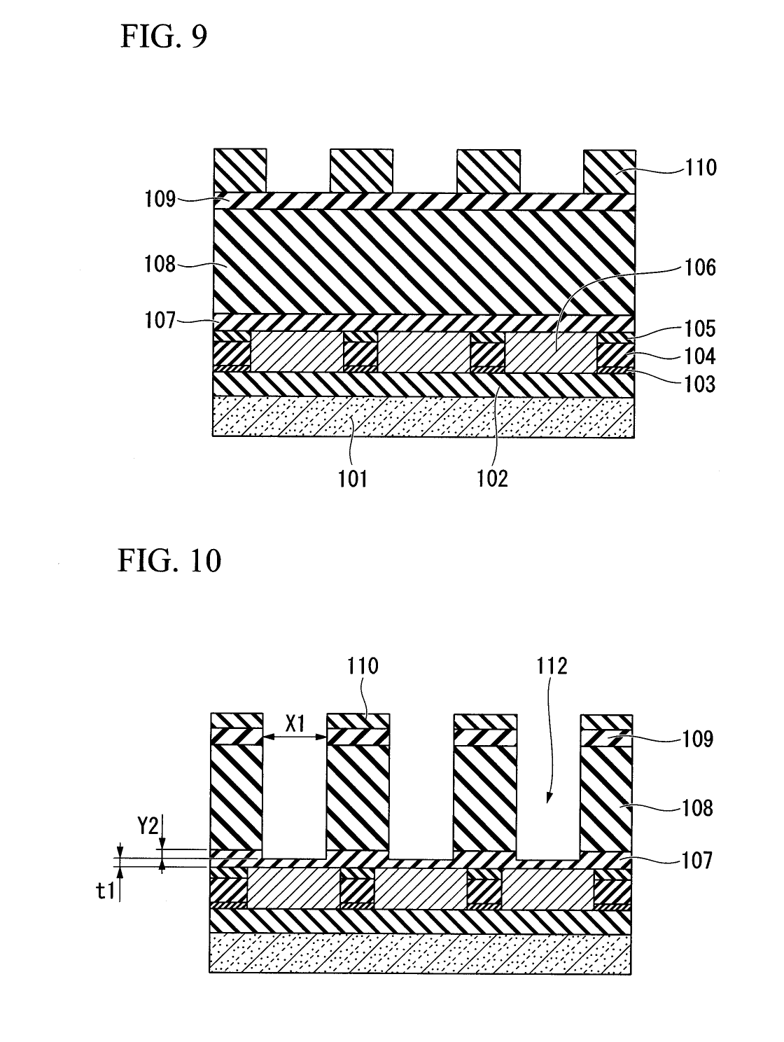

As shown in FIG. 9, a diffusion barrier film 107, an interlayer insulating film 108 and a protection film 109 are stacked on the first metal wiring 106. The diffusion barrier 107 is a SiCN film. The diffusion barrier 107 is formed by a PE-CVD method. The diffusion bather film 107 has a thickness of, for example, about 130 nm. The interlayer insulating film 108 is a low dielectric film such as a SiOC film. The interlayer insulating film 108 is formed by a PE-CVD method. The interlayer insulating film 108 has a thickness of, for example, 600 nm. The protection film 109 is a SiO₂ film. The protection film 109 is formed by a PE-CVD method. The protection film 109 has a thickness of, for example, about 180 nm. Further, a photoresist 110 is exposed and developed so that the photoresist 110 is patterned to expose a portion of the protection film 109.

The diffusion bather 107 is a stopper which prevents a metal serving as a metal wiring material from diffusing to the underlying film. The protection film 109 serves to cover the interlayer insulating film 108 (the low dielectric film), which is weak in mechanical strength, and prevent breakage of the interlayer insulating film 108.

As shown in FIG. 10, a contact hole 112 with a width X1 (about 200 nm) is formed in the interlayer insulating film 108 by dry etching process.

The diffusion barrier film 107 needs to remain so that the first metal wiring 106 is not shown in the dry etching process as will be described later. The diffusion barrier film 107 is removed by a depth Y2 (about 80 nm) when the contact hole 112 is formed. t1 (50 nm) is a thickness of the diffusion barrier film 107 which remains in a bottom of the contact hole 112.

An ashing process is performed so that the photoresist 110 is removed and the protection film 109 is shown.

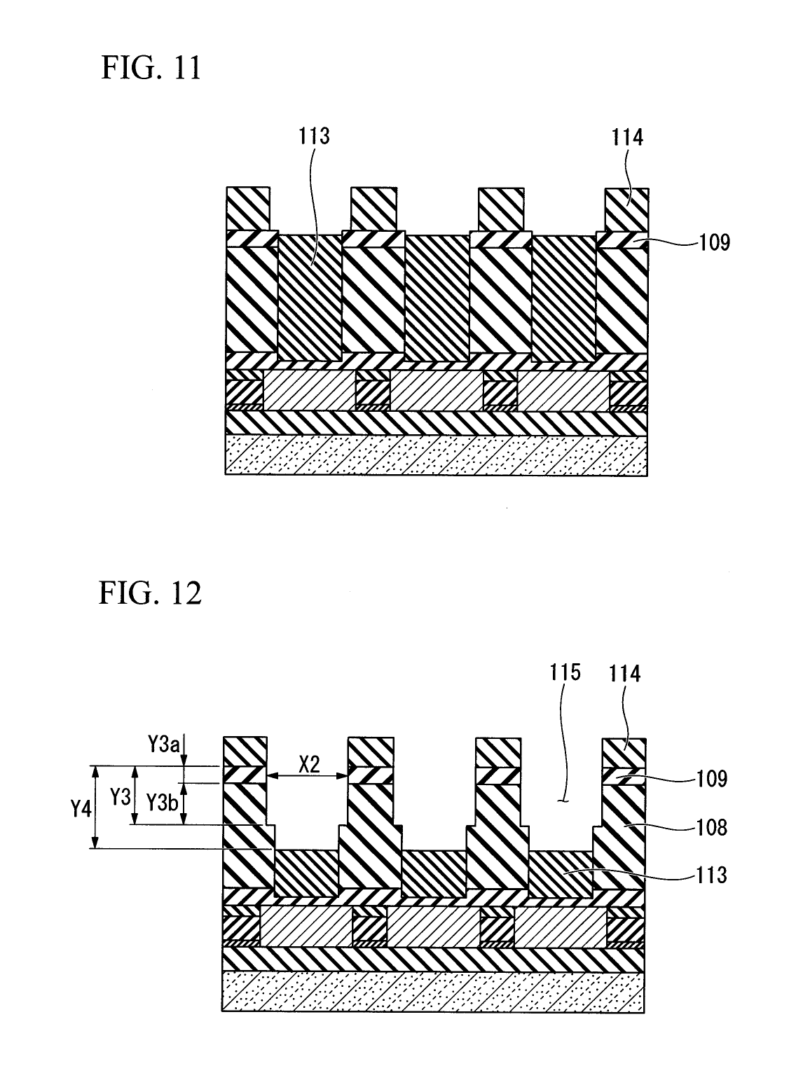

As shown in FIG. 11, a buried film 113 such as a bottom anti-reflection coating (BARC) material film is applied by a spinner method to bury the contact hole 112. The buried film 113 disposed on the protection film 109 is removed by an etch-back method. As a result, the buried film 113 fills the contact hole 112.

A second metal wiring pattern (a groove pattern) is formed using a photoresist 114 on the protection film 109. The second metal wiring pattern has an opening in a position in which Cu is to be buried in the subsequent process. An upper surface of the buried film 113 is shown through the opening of the second metal wiring pattern.

As shown in FIG. 12, a groove pattern 115 with a width X2 (about 250 to 300 nm) and a depth Y3 (about 430 nm) is formed in the interlayer insulating film 108 by dry etching process using the photoresist 114 as a mask.

Since the protection film 109 is covered by the photoresist 114, the thickness of the protection film 109 is unchanged to remain at Y3a (180 nm). A depth of the groove pattern in the interlayer insulating film 108 is Y3b (250 nm).

In the dry etching process, an etch selectivity of the buried film 113 to the interlayer insulating film 108 is set at about 1.2 to 1.4. Thus, the buried film 113 is etched faster than the interlayer insulating film 108. The depth from a top of the protection film 109 to a top of the buried film 113 is Y4 (about 580 nm). Accordingly, a step is formed on side surfaces of the interlayer insulating film 108. The buried film 113 prevents the diffusion barrier film 107 from being etched. It does not matter that the step is formed as long as the diffusion barrier film 107 remains.

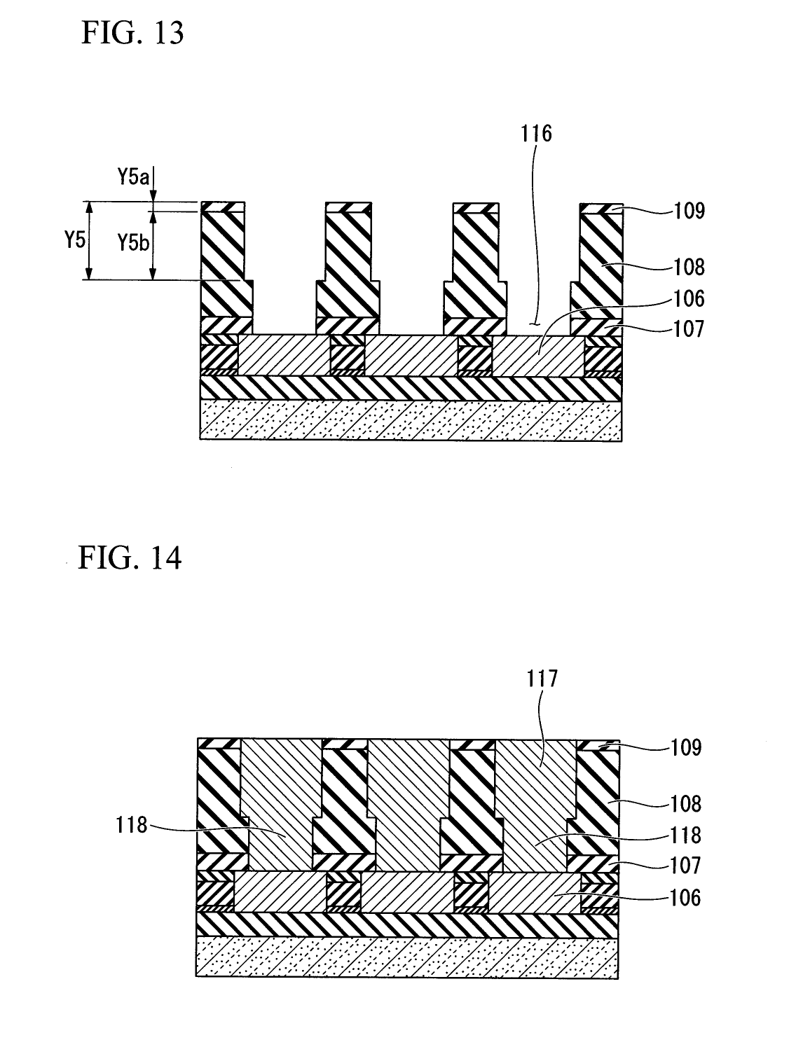

As shown in FIG. 13, the buried film 113 remaining in a lower portion of the groove pattern 115 and the diffusion barrier film 107 are removed by a dry etching process to form a contact hole 116.

In the dry etching process, the first metal wiring 106 formed of Cu is not etched. If the diffusion barrier film 107 is over-etched and removed, the etching process can be completed with the first metal wiring 106 shown. In addition, the photoresist 114 is removed in the etching process. After the photoresist 114 is removed, the protection film 109 may also be slightly etched. Thus, the thickness of the protection film 109 and the depth in the interlayer insulating film 108 are Y5a (100 nm) and Y5b (400 nm), respectively, so that a depth of the groove pattern 115 becomes Y5 (500 nm).

As shown in FIG. 14, a surface of the first metal wiring shown through the contact hole 116 is cleaned. A tantalum (Ta) film with a thickness of about 20 nm and a copper film with a thickness of about 50 nm are formed by a sputtering method to cover surfaces of the contact hole 116 and the groove pattern 115. The tantalum (Ta) film functions as a barrier film. The copper film functions as a seed film. A copper film with a thickness of about 620 nm is formed by a plating method. A portion of the copper film on the protection film 109 is removed by a chemical mechanical polishing (CMP) process. Thereby, a contact plug 118 formed of Cu filling the contact hole 116 and a second metal wiring 117 formed of Cu filling the groove pattern 115 are completed. The second metal wiring 117 is electrically coupled to the first metal wiring 106 disposed thereunder via the contact plug 118.

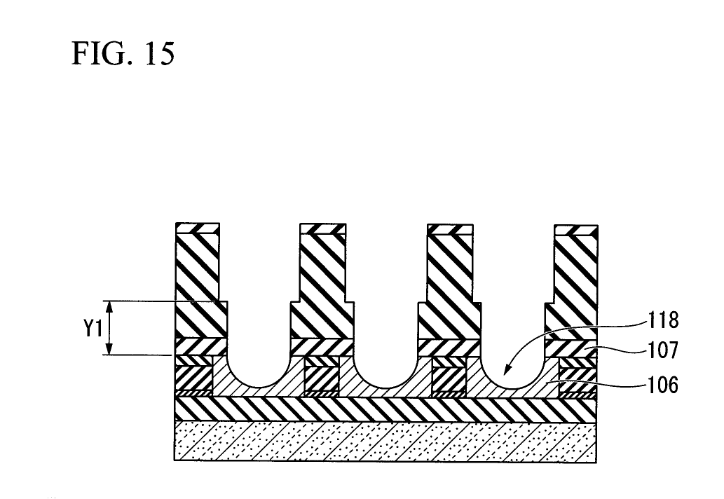

FIG. 15 is a fragmentary cross-sectional elevation view illustrating phenomenon caused in the process for forming the semiconductor device of the related art.

After the dry etching process as shown in FIG. 13, an ashing treatment is performed to remove the remaining photoresist 110. When the thickness t1 of the diffusion bather film 107 in the bottom of the contact hole 112 is 50 nm or less, the upper surface of the first metal wiring 106 formed of copper and disposed below the diffusion barrier film 107 is oxidized by oxygen, which is an ashing gas. The oxidized first metal wiring 106 is eluted in the cleaning treatment after the dry etching process as shown in FIG. 13. A cavity 118 is formed so that the first metal wiring 106 is disconnected or wiring resistance is increased.

Through an evaluation test, the inventor reveals that the thickness t1 of the diffusion barrier film 107 remaining in the bottom of the contact hole 112 shown in FIG. 10 needs to be set to at least 50 nm or more to avoid the above phenomenon described with reference to FIG. 15. Considering ununiformity in the etching process for forming the contact hole 112 and etching uniformity in the whole semiconductor substrate area, it is necessary to initially deposit the diffusion barrier film 107 with a thickness of about 130 nm so that the diffusion bather film 107 with a thickness of at least 50 nm remains.

Since a depth Y1 of the contact plug 16 needs to be set at a predetermined value, it is necessary to thinly deposit the interlayer insulating film 108 when thickly providing the diffusion bather film 107. The diffusion bather (SiCN) film 107 is larger in dielectric constant than the interlayer insulating (SiOC) film 108. When the diffusion barrier film 107 is thickly formed, parasitic capacitance between adjacent contact plugs 116 is increased and thus a high speed operation is inhibited.

When the diffusion barrier film 107 is formed as thinly as possible to suppress an increase in parasitic capacitance, the diffusion barrier film 107 is not completely removed since it is necessary to perform an under-etching process to form the contact hole. Thereby, the contact resistance may be increased.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a wiring, a stack of first, second, and third films, and a contact plug. The stack of first, second, and third films is located over the wiring. The first, second, and third films are stacked in this order. The stack has an opening. The first film is made of the same material as the third film. The contact plug is in the opening. The contact plug is in contact with the wiring.

In some cases, the semiconductor device may include, but is not limited to, the stack having a groove over the opening. A width of the groove is greater than the width of the opening.

In some cases, the semiconductor device may further include, but is not limited to, a transistor electrically coupled to the wiring and a first interlayer insulating film over the transistor. The first interlayer insulating film is below the wiring.

In some cases, the semiconductor device may further include, but is not limited to, a fourth film over the third film. The fourth film is made of the same material as the second film.

In some cases, the semiconductor device may include, but is not limited to, the first film being a diffusion barrier film.

In some cases, the semiconductor device may include, but is not limited to, the third film being an etching stopper.

In some cases, the semiconductor device may include, but is not limited to, the second film being lower in dielectric constant than the first and third films.

In some cases, the semiconductor device may include, but is not limited to, the wiring and the contact plug including copper.

In some cases, the semiconductor device may include, but is not limited to, the first film being smaller in thickness than the third film.

In some cases, the semiconductor device may include, but is not limited to, the first and third films including silicon carbon nitride.

In some cases, the semiconductor device may include, but is not limited to, the second film including silicon oxycarbide.

In another embodiment, a semiconductor device may include, but is not limited to, a substrate, a first interlayer insulating film, a wiring, a first diffusion barrier film, a second interlayer insulating film, a second diffusion barrier film, a third interlayer insulating film, and a contact plug. The first interlayer insulating film is located over the substrate. The wiring is located over the first interlayer insulating film. The wiring includes copper. The first diffusion barrier film is in contact with the wiring. The second interlayer insulating film is located over the first diffusion barrier film. The second diffusion barrier film is located over the second interlayer insulating film. The second diffusion barrier film includes the same material as the first diffusion barrier film. The third interlayer insulating film is located over the second diffusion barrier film. The third interlayer insulating film includes the same material as the second interlayer insulating film. The contact plug is in contact with the wiring. The contact plug includes copper. The contact plug has a side surface being in contact with the first diffusion barrier film, the second interlayer insulating film, the second diffusion barrier film, and the third interlayer insulating film.

In some cases, the semiconductor device may include, but is not limited to, the second interlayer film being lower in dielectric constant than the first diffusion barrier layer.

In some cases, the method may include, but is not limited to, the following elements. The first diffusion barrier film has a first thickness in the range of 10 nm to 30 nm. The second interlayer insulating film has a second thickness in the range of 30 nm to 70 nm. The second interlayer insulating film is in contact with the first diffusion barrier film. The second diffusion barrier film has a third thickness in the range of 40 nm to 80 nm. The second diffusion barrier film is in contact with the second interlayer insulating film.

In still another embodiment, a semiconductor device may include, but is not limited to, a transistor, a first interlayer insulating film, a wiring, a first film, a second film, a third film, and a contact plug. The first interlayer insulating film is located over the transistor. The wiring is located over the first interlayer insulating film. The wiring is electrically coupled to the transistor. The first film is in contact with the wiring. The second film is located over the first film. The third film is located over the third film. The third film is made of the same material as the first film. The contact plug is in contact with the wiring. The contact plug penetrates the first, second, and third films.

In some cases, the semiconductor device may include, but is not limited to, the wiring and the contact plug which include copper.

In some cases, the semiconductor device may further include, but is not limited to, a fourth film over the third film, the fourth film being made of the same material as the second film.

In some cases, the semiconductor device may include, but is not limited to, the second film being lower in dielectric constant than the first and third films.

In some cases, the semiconductor device may include, but is not limited to, the first film being smaller in thickness than the third film.

Hereinafter, a semiconductor device according to an embodiment of the invention will be described in detail with reference to the drawings. In the drawings used for the following description, to easily understand characteristics, there is a case where characteristic parts are enlarged and shown for convenience' sake, and ratios of constituent elements may not be the same as in reality. Materials, sizes, and the like exemplified in the following description are just examples. The invention is not limited thereto and may be appropriately modified within a scope which does not deviate from the concept of the invention.

### First Embodiment

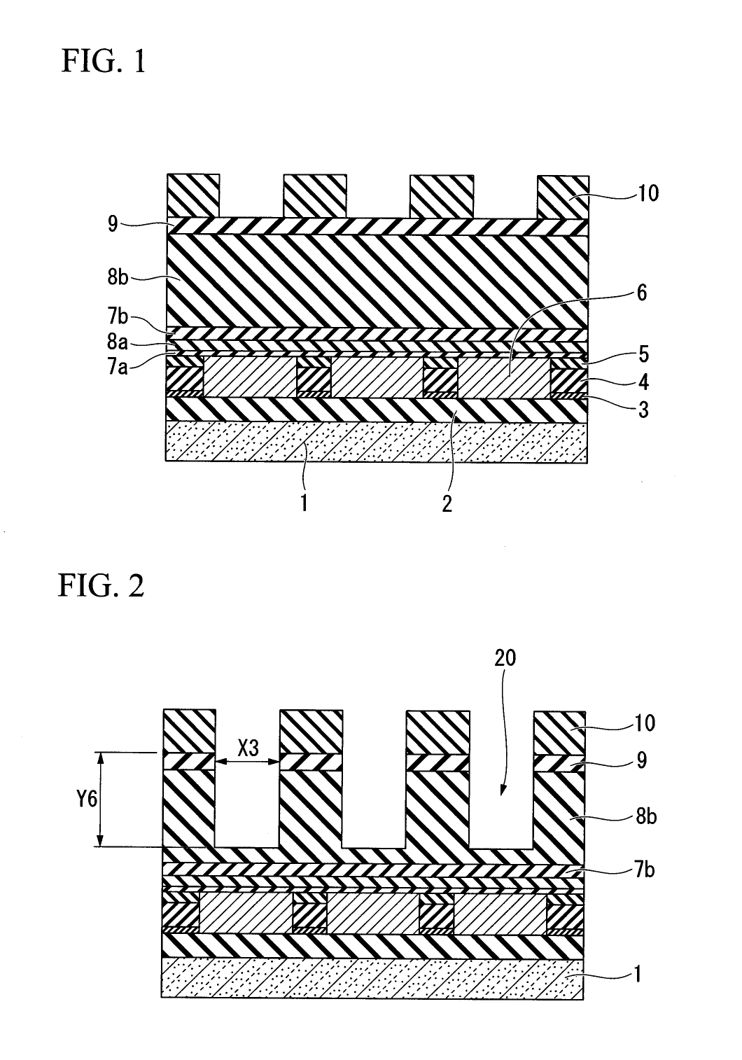

FIGS. 1 to 7 are fragmentary cross-sectional elevation views illustrating structures in steps involved in a method of forming a semiconductor device according to one embodiment of the present invention.

### First Process

As shown in FIG. 1, the first process may include, but is not limited to, sequentially forming a first metal wiring (the first metal wiring layer) 6, a first diffusion barrier film 7a, a first insulating film 8a, a second insulating film 7b, and a third insulating film 8b on a semiconductor substrate 1. The first diffusion barrier film 7a can prevent metal of the first metal wiring 6 from diffusing. The second insulating film 7b is formed of the same material as the first diffusion barrier film 7a.

Hereinafter, the first process will be described in detail.

As shown in FIG. 1, the semiconductor substrate 1 such as a silicon substrate, on which the first metal wiring (the first metal wiring layer) 6 is formed using cupper (Cu), is prepared.

An isolation region (not shown) is provided in the semiconductor substrate 1 such as the silicon substrate. The isolation region is formed by an insulating film such as a silicon oxide film or a silicon nitride film. A diffusion region (an active region) is defined by the isolation region. An impurity is introduced into the diffusion region by an implantation method or the like.

A MOS transistor (not shown) having a gate electrode is formed on a main surface of the semiconductor substrate 1. The MOS transistor is electrically coupled to a wiring (not shown) or a contact plug (not shown) formed in an interlayer insulating film 2. The interlayer insulating film 2 is formed over the MOS transistor.

A diffusion barrier film 3 such as a silicon carbon nitride (SiCN) film with a thickness of about 30 nm is formed on the interlayer insulating film 2 by a plasma enhanced-chemical vapor deposition (PE-CVD) method. An interlayer insulating film 4 with a thickness of about 110 nm is formed on the diffusion barrier film 3 by a PE-CVD method. The interlayer insulating film 4 is a low dielectric film such as a silicon oxycarbide (SiOC) film. A protection film 5 of a silicon oxide (SiO₂) film with a thickness of about 50 nm is formed on the interlayer insulating film 4 by a PE-CVD method. A trench is formed to penetrate the stack of the diffusion barrier film 3, the interlayer insulating film 4 and the protection film 5. The first metal wiring (the first metal wiring layer) 6 filling the trench is formed. The first metal wiring (the first metal wiring layer) 6 is electrically coupled to the wiring or the contact plug formed in the interlayer insulating film 2. The first metal wiring 6 is electrically coupled to the MOS transistor via the wiring or the contact plug formed in the interlayer insulating film 2.

As shown in FIG. 1, the first diffusion barrier film 7a with a thickness of about 20 nm is formed on the first metal wiring (the first metal wiring layer) 6 by a PE-CVD method. A first interlayer insulating film (the first insulating film) 8a with a thickness of about 50 nm is formed on the first diffusion barrier film 7a by a PE-CVD method. A second diffusion barrier film (the second insulating film) 7b with a thickness of about 60 nm is formed on the first interlayer insulating film 8a by a PE-CVD method. A second interlayer insulating film (the third insulating film) 8b with a thickness of about 550 nm is formed on the second diffusion barrier film 7b by a PE-CVD method. A protection film 9 (a fourth insulating film), which is a SiO₂ film, with a thickness of about 180 is formed on the second interlayer insulating film 8b nm by a PE-CVD method. A photoresist 10 is exposed and developed so that a part of the protection film (the fourth insulating film) 9 is shown.

The first diffusion barrier film 7a is a film for preventing diffusions of metal of the first metal wiring (the first metal wiring layer) 6 and a second metal wiring (a second metal wiring layer) 17 to be described later. The first diffusion barrier film 7a may be a SiCN film.

The first diffusion barrier film 7a is to prevent metal diffusion and to suppress increase in parasitic capacitance. The thickness of the first diffusion barrier film 7a may be about 10 nm to 30 nm to prevent metal diffusion and to suppress increase in parasitic capacitance.

The second diffusion barrier film (the second insulating film) 7b is formed of the same material as the first diffusion barrier film 7a. The second diffusion barrier film 7b is to prevent the metal diffusion. The second diffusion barrier film 7b is to suppress increase in parasitic capacitance. In this embodiment, the second diffusion barrier film 7b also functions as a stopper for dry etching process in forming a contact hole.

The thickness of the second diffusion barrier film (the second insulating film) 7b may be about 40 nm to 80 nm from the viewpoint of assuring a stopper function for dry etching process and suppressing an increase in parasitic capacitance. The second diffusion barrier film 7b is greater in thickness than the first diffusion barrier film 7a.

The first interlayer insulating film (the first insulating film) 8a and the second interlayer insulating film (the third insulating film) 8b may be a low dielectric film such as a SiOC film to reduce parasitic capacitance. The first and second interlayer insulating film 8a and 8b may be lower in dielectric constant than the first and second diffusion barrier film 7a and 7b.

The thickness of the first interlayer insulating film (the first insulating film) 8a may be about 30 nm to 70 nm to perform a stopper function for dry etching and to suppress increase in parasitic capacitance.

As described above, the semiconductor device of the embodiment includes the multi-layered diffusion barrier structure over the first metal wiring layer, instead of the single-layered diffusion barrier structure. The multi-layered metal-diffusion stopper structure is to prevent diffusion of the metal of the first metal wiring layer, to prevent the first metal layer from receiving damages, and to suppress increasing parasitic capacitance between wirings. The multi-layered diffusion barrier structure includes plural diffusion barrier layers, in some cases, the first and second diffusion barrier layers and the inter-layer insulator between the first and second diffusion barrier layers.

### Second Process

As shown in FIG. 2, a second process may include, but is not limited to, etching the third insulating film 8b to form a first contact hole 20 in the third insulating film 8b. During the etching process, an etch selectivity of the third insulating film 8b to the second insulating film 7b is set as a first etch selectivity.

Hereinafter, the second process will be described in further detail.

As shown in FIG. 2, a dry etching process is performed to form the contact hole (the first contact hole) 20 with a width X3 (about 200 nm) and a depth Y6 (about 690 nm) in the second interlayer insulating film 8b.

Specific dry etching conditions are shown in the following (1).
(1) Dry Etching Process Conditions
(i) Method: parallel plate plasma etching process
(ii) Pressure: 30 mTorr
(iii) Process gas [flow rate]: perfluorocyclobutane (C₄F₈) [8 sccm]/difluoromethane (CH₂F₂) [20 sccm]/argon (Ar) [700 sccm]/nitrogen (N₂) [50 sccm]/oxygen (O₂) [23 sccm]
(iv) Bias power: 500 W (upper electrode)/2500 W (lower electrode)

In the dry etching process, there may be set the condition that the second interlayer insulating film (the third insulating film) 8b is etched as vertically as possible. Thus, there may be decreased the etch selectivity (the first etch selectivity) of the second interlayer insulating film (the third insulating film) 8b to the second diffusion barrier film (the second insulating film) 7b.

Therefore, the contact hole (the first contact hole) 20 may penetrate the second diffusion barrier film (the second insulating film) 7b. In order to avoid the penetration of the diffusion barrier film (the second insulating film) 7b, the dry etching process is stopped before the first contact hole 20 reaching the second diffusion barrier film (the second insulating film) 7b as shown in FIG. 2.

### Third Process

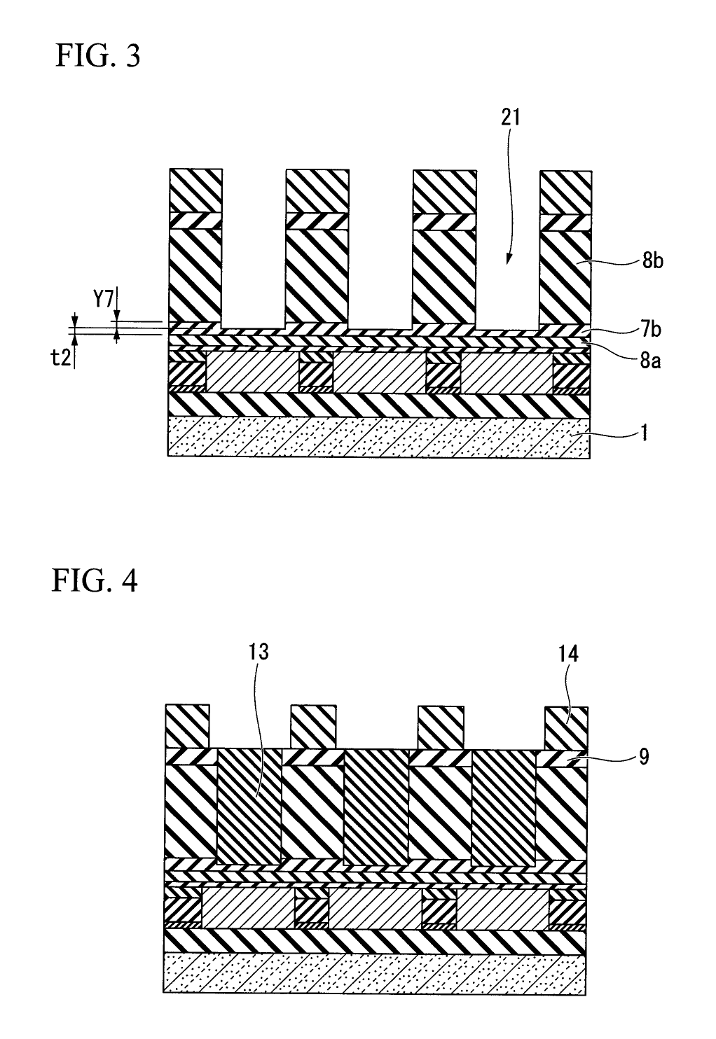

As shown in FIG. 3, in a third process, the third insulating film 8b and the second insulating film 7b below the first contact hole 20 are dry-etched under the condition (the condition set to a second etch selectivity) where the third insulating film 8b is greater in etching rate than the second insulating film 7b. Thereby, a second contact hole 21 is formed. A bottom of the second contact hole 21 is in the second insulating film 7b. The second contact hole 21 is formed by lowering a bottom of the first contact hole 20. Since the second etch selectivity is set larger than the first etch selectivity, an etching process is easily performed without penetrating the second insulating film 7b.

Specific dry etching conditions are illustrated in the following (2).
(2) Dry Etching Process Conditions
(i) Method: parallel plate plasma etching
(ii) Pressure: 50 mTorr
(iii) Process gas [flow rate]: perfluorocyclobutane (C₄F₈) [8 sccm]/argon (Ar) [600 sccm]/nitrogen (N₂) [440 sccm]
(iv) Bias power: 400 W (upper electrode)/2500 W (lower electrode)

In the conditions (2), the etch selectivity (the second etch selectivity) of the second interlayer insulating film (the third insulating film) 8b to the second diffusion barrier film (the second insulating film) 7b may be set to 3 or more. In some cases, the second etch selectivity may be set to about 5.

The dry etching process is completed when the second contact hole 21 reaches the second diffusion barrier film (the second insulating film) 7b. It is unnecessary to precisely control the remaining film thickness t2 to form the second contact hole 21. There are the first interlayer insulating film (the first insulating film) 8a with a thickness of about 50 nm and the first diffusion barrier film (the diffusion barrier film) 7a with a thickness of about 20 nm under the second diffusion barrier film 7b. The first interlayer insulating film (the first insulating film) 8a and the first diffusion barrier film (the diffusion barrier film) 7a function as a diffusion barrier film. Thus, it can be regarded that the diffusion barrier film with a thickness of 50 nm or more is located on the first metal wiring (the first metal wiring layer) 6 regardless of the remaining film thickness t2 of the second diffusion barrier film (the second insulating film) 7b.

### Fourth Process

As shown in FIG. 4, a fourth process may include, but is not limited to, the following processes. A buried film (fifth insulating film) 13 fills the second contact hole 21. A photoresist pattern 14 is formed on the protection film 9. The photoresist pattern 14 has a groove pattern corresponding to a groove pattern to be filled by a conductive film for the second metal wiring 17 which will be described later. The second metal wiring 17 is electrically coupled to the first metal wiring 6. Hereinafter, the fourth process will be described in further detail.

An ashing treatment is performed to remove the photoresist 10. The protection film (the fourth insulating film) 9 is shown.

As shown in FIG. 4, the buried film (the fifth insulating film) 13 a bottom anti-reflection coating (BARC) material or the like is formed to be buried in the contact hole (the second contact hole) 21 by a spinner method. The buried film (the fifth insulating film) 13 on the protection film (the fourth insulating film) 9 is removed by an etch-back method so that the buried film (the fifth insulating film) 13 fills the contact hole (the second contact hole) 21.

The photoresist (a photoresist pattern) 14 having the groove pattern is formed on the protection film (the fourth insulating film) 9. The groove pattern (the second metal wiring pattern) corresponds to the groove pattern to be filled by the conductive film (for example, Cu) for the second metal wiring 17 in subsequent processes. An upper surface of the buried film 13 is shown through the opening of the second metal wiring (the second metal wiring) pattern.

### Fifth Process

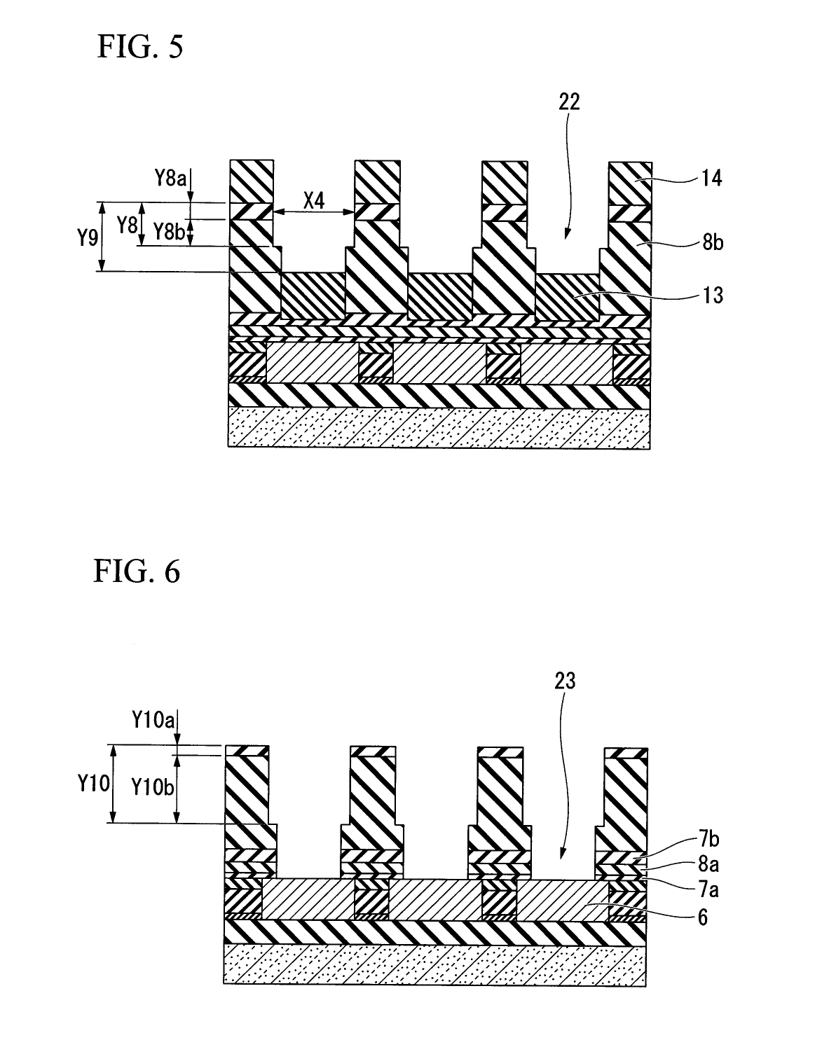

As shown in FIG. 5, the fifth process may include, but is not limited to, etching the fifth insulating film 13 and the third insulating film 8b using the photoresist pattern 14 as a mask so that a portion of the fifth insulating film 13 remains in the second contact hole 21.

Hereinafter, the fifth process will be described in further detail.

As shown in FIG. 5, a groove pattern 22 with a width X4 (about 250 to 300 nm) and a depth Y8 (about 380 nm) is formed in the second interlayer insulating film (the third insulating film) 8b and the protection layer 9 by a dry etching process.

Specific dry etching conditions are illustrated in the following (3).

(3) Dry Etching Process Conditions
(i) Method: parallel plate plasma etching
(ii) Pressure: 125 mTorr
(iii) Process gas [flow rate]: tetrafluoromethane (CF₄) [200 sccm]/trifluoromethane (CHF₃) [100 sccm]
(iv) Bias power: 1000 W (upper electrode)/500 W (lower electrode)

In the dry etching process, an etch selectivity of the buried film (the fifth insulating film) 13 to the second interlayer insulating film (the third insulating film) 8b may be set to about 1.1 to 1.6. In some cases, the etch selectivity of the buried film (the fifth insulating film) 13 to the second interlayer insulating film (the third insulating film) 8b may be set to about 1.2 to 1.4. In this case, as shown in FIG. 5, the buried film 13 is etched faster than the second interlayer insulating film 8b so that a depth (Y9) of the groove pattern 22 from the top of the protection film 9 to a top of the buried film 13 is about 580 nm. A depth Y8b of the groove pattern 22 in the second interlayer insulating film (the third insulating film) 8b is about 200 nm.

### Sixth Process

As shown in FIG. 6, a sixth process may include, but is not limited to, forming a contact hole (third contact hole) 23 by etching the fifth insulating film 13 in the second contact hole 21 and the second insulating film 7b, the first insulating film 8a, and the first diffusion barrier film 7a below the fifth insulating film 13 by lowering a bottom of the second contact hole 21. A surface of the first metal wiring (the first metal wiring layer) 6 is shown through the contact hole 23.

Hereinafter, the sixth process will be described in further detail.

As shown in FIG. 6, there are removed the buried film (the fifth insulating film) 13 remaining below the groove pattern 22 (within the second contact hole 21), and the second diffusion barrier film (the second insulating film) 7b, the first interlayer insulating film (the first insulating film) 8a, and the first diffusion barrier film (the diffusion barrier film) 7a below the buried film 13. The surface of the first metal wiring (the first metal wiring layer) 6 is shown, thereby forming the contact hole (the third contact hole) 23.

Specific dry etching conditions are illustrated in the following (4).

(4) Dry Etching Process Conditions
(i) Method: parallel plate plasma etching
(ii) Pressure: 50 mTorr
(iii) Process gas [flow rate]: tetrafluoromethane (CFO [175 sccm]/nitrogen (N₂) [50 sccm]
(iv) Bias power: 500 W (upper electrode)/200 W (lower electrode)

In the dry etching process, it is difficult to etch the first metal wiring (the first metal wiring layer) 6 formed of copper. Over-etching the first diffusion barrier film (diffusion barrier film) 7a of about 20% is performed to remove the first diffusion barrier film (diffusion bather film) 7a. The dry etching process can be completed with the first metal wiring (the first metal wiring) 6 shown.

The photoresist 14 is removed during the etching process. The protection film (the fourth insulating film) 9 and the second interlayer insulating film (the third insulating film) 8b are slightly etched. The thickness Y10a of the protection film (the fourth insulating film) 9 is 100 nm. The depth Y10b of the third contact hole 23 in the second interlayer insulating film (the third insulating film) 8b is 400 nm. The depth Y10 of the groove pattern 22 is 500 nm. Thus, it is possible to control the dimensions Y10a, Y10a, and Y10 to be the same as in the related art. Here, the etch selectivity between the first interlayer insulating film (the first insulating film) 8a, the first diffusion barrier film (the diffusion barrier film) 7a, and the second diffusion barrier film (the second insulating film) 7b is almost 1. The first interlayer insulating film (the first insulating film) 8a, the first diffusion barrier film (the diffusion barrier film) 7a, and the second diffusion bather film (the second insulating film) 7b are etched in the same rate. The groove pattern 22 is formed with a smaller depth Y8 than in the related art in advance since the sum of the thicknesses of the first interlayer insulating film (the first insulating film) 8a and the first diffusion barrier film (the diffusion barrier film) 7a and t2 shown in FIG. 3 is greater than the thickness t1 shown in FIG. 10 in the related art.

After the etching process, the upper surface of the first metal wiring (the first metal wiring layer) 6 is cleaned, at about 25° C., in a mixing chemical such as dimethyl sulfoxide ((CH₃)₂SO) ammonium fluoride (NH₄F), and hydrofluoric acid (HF).

### Seventh Process

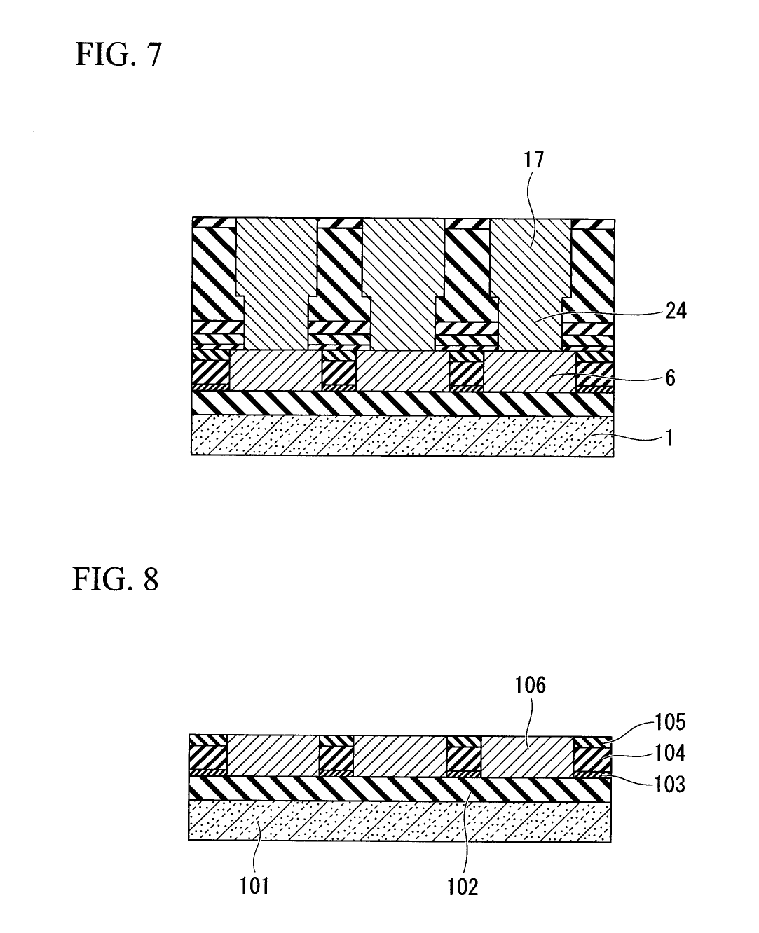

As shown in FIG. 7, a seventh process may include, but is not limited to, forming a conductive film in the third contact hole 23 to form the second metal wiring 17.

Hereinafter, the seventh process will be described in further detail.

As shown in FIG. 7, a tantalum (Ta) film with a thickness of about 20 nm as a barrier film is formed to cover side surfaces of the contact hole (the third contact hole) 23 and the groove pattern 22 by a sputtering method. A first copper (Cu) film with a thickness of about 50 nm as a seed film is formed on the barrier film by a sputtering method. Then, a second copper film with a thickness of about 620 nm is formed by a plating method.

After the first and second copper films on the protection film (the fourth insulating film) 9 is removed by a chemical mechanical polishing (CMP) process, a contact plug 24 (a first portion of the second metal wiring layer) in which the first and second copper films fill the contact hole 23 and a second metal wiring (a second portion of the second metal wiring layer) 17 in which the first and second copper films fill the groove pattern 22 are completed. The contact plug 24 and the second metal wiring 17 penetrate the first diffusion bather film 7a, the first insulating film 8a, the second insulating film 7b, and the third insulating film 8b. The second metal wiring (the second portion of the second metal wiring layer) 17 is electrically connected to the underlying first metal wiring (the first metal wiring layer) 6 via the contact plug (the first portion of the second metal wiring layer) 24.

A total deposition film thickness of the first diffusion barrier film (the diffusion barrier film) 7a and the second diffusion bather film (the second insulating film) 7b is 80 nm. The total deposition film thickness can be suppressed to be a film thickness of about 60% of 130 nm in the related art.

A semiconductor device will be described according to the present embodiment with reference to FIG. 7.

The semiconductor device according to the present embodiment may include, but is not limited to, the following elements. The first metal wiring (the first metal wiring layer) 6 is formed on the semiconductor substrate 1. The first diffusion barrier film 7a is disposed on the first metal wiring 6 (the first metal wiring layer). The first diffusion barrier film 7a prevents metal of the first metal wiring 6 (the first metal wiring layer) from diffusing. The first insulating film 8a is disposed on the first diffusion barrier film 7a. The second insulating film 7b is disposed on the first insulating film 8a. The second insulating film 7b is formed of the same material as the diffusion barrier film. The third insulating film 8b is disposed on the second insulating film 7b. The second metal wiring 17 and the contact plug 24 (the second metal wiring layer) fill the third contact hole 23 formed in the first diffusion barrier film 7a, the first insulating film 8a, the second insulating film 7b, and the third insulating film 8b. The contact plug 24 has a side surface being in contact with the first diffusion bather film 7a, the first insulating film 8a, the second insulating film 7b, and the third insulating film 8b. The second metal wiring 17 and the contact plug 24 (the second metal wiring layer) are electrically connected to the first metal wiring 6.

In the present embodiment, the diffusion bather film is divided into two layers and an interlayer insulating film is inserted between the divided diffusion barrier films. The upper diffusion barrier film functions as an etch stopper. The lower diffusion barrier film prevents diffusion of metal of the underlying metal wiring. Providing the upper and lower barrier films prevents failure occurrence in forming the semiconductor device even if the diffusion barrier film is getting thinner.

Thickness values and etching conditions are merely exemplary and are not limited thereto. The thickness values and the etching condition may be appropriately modified.

The semiconductor device and the method of forming the same according to present embodiment can be applied to a semiconductor device and a method of forming the same in which a metal wiring is formed without damage of an underlying metal wiring and parasitic capacitance between wirings is reduced.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a wiring;
a stack of first, second, and third films over the wiring, the first, second, and third films being stacked in this order, the stack having an opening, the first film being made of the same material as the third film; and
a contact plug in the opening, the contact plug being in contact with the wiring.

2. The semiconductor device according to claim 1, wherein the stack has a groove over the opening, a width of the groove being greater than the width of the opening.

3. The semiconductor device according to claim 1, further comprising:
a transistor electrically coupled to the wiring; and
a first interlayer insulating film over the transistor, the first interlayer insulating film being below the wiring.

4. The semiconductor device according to claim 1, further comprising:
a fourth film over the third film, the fourth film being made of the same material as the second film.

5. The semiconductor device according to claim 1, wherein the first film is a diffusion barrier film.

6. The semiconductor device according to claim 1, wherein the third film is an etching stopper.

7. The semiconductor device according to claim 1, wherein the second film is lower in dielectric constant than the first and third films.

8. The semiconductor device according to claim 1, wherein the wiring and the contact plug comprise copper.

9. The semiconductor device according to claim 1, wherein the first film is smaller in thickness than the third film.

10. The semiconductor device according to claim 1, wherein the first and third films comprise silicon carbon nitride.

11. The semiconductor device according to claim 1, wherein the second film comprises silicon oxycarbide.

12. A semiconductor device comprising:
a substrate;
a first interlayer insulating film over the substrate;
a wiring over the first interlayer insulating film, the wiring comprising copper;
a first diffusion barrier film in contact with the wiring;
a second interlayer insulating film over the first diffusion barrier film;
a second diffusion barrier film over the second interlayer insulating film, the second diffusion barrier film comprising the same material as the first diffusion barrier film;
a third interlayer insulating film over the second diffusion barrier film, the third interlayer insulating film comprising the same material as the second interlayer insulating film; and
a contact plug in contact with the wiring, the contact plug comprising copper, the contact plug having a side surface being in contact with the first diffusion barrier film, the second interlayer insulating film, the second diffusion barrier film, and the third interlayer insulating film.

13. The semiconductor device according to claim 12, wherein the second interlayer insulating film is lower in dielectric constant than the first diffusion barrier layer.

14. The semiconductor device according to claim 12, wherein
the first diffusion barrier film has a first thickness in the range of 10 nm to 30 nm,
the second interlayer insulating film has a second thickness in the range of 30 nm to 70 nm, and the second interlayer insulating film is in contact with the first diffusion barrier film, and
the second diffusion barrier film has a third thickness in the range of 40 nm to 80 nm, and the second diffusion barrier film is in contact with the second interlayer insulating film.

15. A semiconductor device comprising:
a transistor;
a first interlayer insulating film over the transistor;
a wiring over the first interlayer insulating film, the wiring being electrically coupled to the transistor;
a first film in contact with the wiring;
a second film over the first film;
a third film over the third film, the third film being made of the same material as the first film; and
a contact plug in contact with the wiring, the contact plug penetrating the first, second, and third films.

16. The semiconductor device according to claim 15, wherein the wiring and the contact plug comprise copper.

17. The semiconductor device according to claim 15, further comprising:
a fourth film over the third film, the fourth film being made of the same material as the second film.

18. The semiconductor device according to claim 17, wherein the second film is lower in dielectric constant than the first and third films.

19. The semiconductor device according to claim 15, wherein the first film is smaller in thickness than the third film.
